(19) United States
(12) Patent Application Publication
(10) Pub. No.: US 2005/0004691 A1
(43) Pub. Date: Jan. 6, 2005

(54) Versatile system for processing digital audio signals

(76) Inventor: Christoper A. Edwards, McKinney, TX (US)

Correspondence Address: TEXAS INSTRUMENTS INCORPORATED, P O BOX 655474, M/S 3999, DALLAS, TX, 75265, US

(21) Appl. No.: 10/613,188

(22) Filed: Jul. 3, 2003

(51) Int. Cl. G06F 17/00; H03G 3/00

(52) U.S. Cl. 700/94; 381/98; 381/61

(57) ABSTRACT

The present invention provides a system for processing digital audio signals according to modifications selected by an equipment end-user. A signal acquisition function (200) acquires a digital input signal (202). A user interface function (214) is operatively associated with a user interface (216), and is designed to receive the digital input digital signal and to generate a user-selected fundamental frequency. A comparator function (206) receives the digital input digital audio signal, and the user-selected fundamental frequency. The comparator function outputs a portion of the digital input signal, at the user-selected fundamental frequency, to a harmonics generation function (218). The harmonics generation function receives the portion of the digital input signal at the user-selected fundamental frequency and generates a number of signal harmonics for that portion of the digital input signal based on a defined harmonics profile. A summing function (210) adds the signal harmonics to the digital input signals, and outputs a user-modified signal (220).

### TECHNICAL FIELD OF THE INVENTION

The present invention relates generally to the field of signal processing and, more particularly, to apparatus and methods for processing digital audio signals so as to selectively alter specific aesthetic properties of a given sound waveform.

### BACKGROUND OF THE INVENTION

The continual demand for enhanced performance of consumer oriented multimedia and communications systems has resulted in a number of improvements and innovations in communication technologies. A great number of these improvements and innovations concern the “digitization” of sensory-based information. This “digitization” involves the conversion of analog audio and video signals into digital representations, which are easier to process and communicate. In most cases, an analog input signal is sampled at some selected resolution, and a digital “model” of the analog signal is created therefrom. Depending upon the resolution of the sampling, relatively minor to relatively large portions of the original analog signal may be omitted from the resulting digitized signal. This can be especially critical in signals that have many frequent, but subtle, variations.

In many multimedia and communication applications, the digitized signals are often preferable to the original analog signal. Digital signals enable a wide variety of information storage, playback, and manipulation options. In many applications, the loss of resolution between a full analog signal, and the digital signal modeled from it, are imperceptible to most users. There are some applications, however, where users are capable of discerning aesthetic differences between the two signal types, and those differences are of importance to them. One such application is the recording and playback of acoustic signals, particularly vocal and music tracks.

Often, vocal or musical signals are captured from an analog input (e.g., a microphone) and recorded or stored for later processing or playback on some sort of digital media (e.g., a compact disc). To a lesser extent, such analog acoustic signals may be captured, transformed to digital, and broadcast on a real-time basis. With all such applications, there are a number of end-users who find that the digitization of the acoustic signals results in a playback or reception signal that is, aesthetically, less than pleasing. Such end-users might perceive that the resultant digitized acoustic signal is somewhat “cold” or “sterile”—lacking the richness and depth of a fully analog signal. This perception of digital coldness can be reduced where the digital modeling of an analog input signal involves a very complex, high-resolution sampling of that input signal. Such complex digital modeling, however, increases the cost and reduces the efficiency of the digitization process and is not, therefore, viable for most commercial applications.

Thus, there have been some previous attempts to modify certain aesthetics of digitized acoustic signals. Certain conventional systems have focused on modifying only a certain range digital signals in a limited way. For example, there are a number of conventional systems that augment the perceived bass content or response of a digital acoustic signal. In most cases, these systems focus only a limited sub-range of the acoustic signal spectrum (i.e., low frequency)—doing nothing to address the aesthetics of the remainder of the spectrum (i.e., mid-range and high frequency). Other conventional systems offer an “all-or-nothing” type of augmentation, where the entire signal spectrum is processed in a uniform manner. Often, such systems over-process the signal—inefficiently amplifying the entire signal without targeting specific perceptual variances. In most all types of conventional systems, the end-user's ability to selectively augment varying portions of the digitized signal spectrum is limited, if available at all.

Furthermore, most such conventional systems rely on adding a number of harmonics to a digital signal. Often, the number of harmonics and their relative weighting is predetermined and fixed. Thus, an end-user gets a “take-it-or-leave-it” augmentation scheme so that typically adds both odd and even order harmonics, often in an increasing proportion. In many instances, the addition of odd order harmonics may result in an aesthetically harsh or unpleasant sound. Most conventional systems thus provide a limited processing scheme—one that does not allow an end-user to select or omit specific harmonics from the aesthetic augmentation process.

Of course, the aesthetic quality of a given digital audio signal is a subjective matter that varies from listener to listener. One user's perception of a warm, aesthetically pleasing audio signal may differ greatly from another's. Thus, systems that provide little or no end-user adjustment may be less desirable than systems that do provide end-user adjustment.

As a result, there is a need for a system that aesthetically augments digital audio signals in a versatile manner while providing end-user-selectable augmentation characteristics, processing digital audio signals in an efficient and commercially viable way.

### SUMMARY OF THE INVENTION

The present invention provides a system that aesthetically augments digital audio signals in a highly versatile and adaptable manner. The system of the present invention provides end-user-selectable augmentation characteristics and schemes, in an efficient and commercially viable way. Specifically, the present invention provides a digital signal modification window. An end-user may specify specific processing characteristics of that window, such as the inclusion and relative weighting of certain signal harmonics. The end-user may then, using the modification window, scan through a given digital audio signal until placing the window in a frequency band that provides an aesthetically desirable result. The location and configuration of the window may be “locked” or stored for repeated or later use, and multiple instances of the window may be implemented to concurrently modify varying portions of a given digital signal spectrum. The present invention thus provides a high level of user selectivity in a highly efficient manner, overcoming limitations associated with conventional methods and systems.

More specifically, the present invention provides a method of processing a digital audio signal. The method includes providing a digital audio signal having a defined frequency spectrum. The method provides and operates a user interface to select a fundamental frequency from the frequency spectrum. A harmonics generation function is provided to generate a number of signal harmonics based on the fundamental frequency. The generated signal harmonics are then added to the digital audio signal at the fundamental frequency.

The present invention also provides a device for processing digital signals. The device comprises a signal acquisition function, adapted to output a digital input signal. The device further comprises a user interface function, communicatively coupled to a user interface, and adapted to receive the digital input digital audio signal and to provide a user-selected fundamental frequency. A comparator function is included, and adapted to receive the digital input digital audio signal and the user-selected fundamental frequency, and to output a portion of the digital input signal at the user-selected fundamental frequency. The device includes a harmonics generation function, adapted to receive from the comparator function the portion of the digital input signal at the user-selected fundamental frequency, and to generate a number of signal harmonics for the portion of the digital input signal at the user-selected fundamental frequency based on a defined harmonics profile. The device further includes a summing function, adapted to receive the signal harmonics from the harmonics generation function and to add the signal harmonics to the digital input signal at the user-selected fundamental frequency.

The present invention further provides system for providing user-modified processing of a digital audio signal. The system has a digital input audio signal having a defined signal spectrum. The system comprises a harmonics profile. In one embodiment of the present invention, the harmonics profiles is adapted to specify generation of a second harmonic of weight equal to 75% of the digital input audio signal, a fourth harmonic of weight equal to 50% of the digital input audio signal, and a sixth harmonic of weight equal to 25% of the digital input audio signal. The system further comprises a harmonics generation function, adapted to generate the harmonics specified in the harmonics profile from the digital input audio signal at a user-selected fundamental frequency. The system includes a summing function, adapted to add the harmonics generated by the harmonics generation function to the digital input audio signal at the user-selected fundamental frequency to generate a modified output audio signal. The system further includes a user feedback mechanism, adapted to communicate the modified output audio signal to a user. The system further provides a user interface, adapted to provide the user the ability to move the user-selected fundamental frequency throughout the signal spectrum of the digital input audio signal.

Other features and advantages of the present invention will be apparent to those of ordinary skill in the art upon reference to the following detailed description taken in conjunction with the accompanying drawings.

### BRIEF DESCRIPTION OF THE DRAWINGS

For a better understanding of the invention, and to show by way of example how the same may be carried into effect, reference is now made to the detailed description of the invention along with the accompanying figures in which corresponding numerals in the different figures refer to corresponding parts and in which:

FIG. 1 is an illustration of one embodiment of a signal processing system according to the present invention;

FIG. 2 is an illustration of another embodiment of a signal processing system according to the present invention; and

FIG. 3 is an illustration of one embodiment of a signal harmonics profile according to the present invention.

### DETAILED DESCRIPTION OF THE INVENTION

While the making and using of various embodiments of the present invention are discussed in detail below, it should be appreciated that the present invention provides many applicable inventive concepts, which can be embodied in a wide variety of specific contexts. The present invention will now be described in conjunction with the modification of digital audio signals. The present invention provides a versatile system that provides highly efficient end-user modification of a digital signal, particularly digital audio signals. Although the present invention is hereinafter described in reference to aesthetic alteration of a digital audio signal, the principles and teachings of the present invention are readily adaptable to other signal processing applications. The specific embodiments discussed herein are merely illustrative of specific ways to make and use the invention and do not limit the scope of the invention.

The present invention defines a system that aesthetically augments digital audio signals based on end-user-selectable augmentation characteristics and schemes. The present invention recognizes that, especially in commercial audio applications, the perception of sound quality is a subjective matter—suggesting, if not militating, a user-adjustable system. The present invention provides a modification window, within which an end-user may specify processing characteristics such as the inclusion, and relative weighting, of certain signal harmonics. For a given digital input signal, the end-user ranges the window through the frequency spectrum of the input signal until locating a position for the window that provides the most aesthetically desirable digital output signal. The window may then be left in place to provide the desired output for that particular input signal. The window location may be stored or otherwise associated with a particular input signal, and then re-positioned for a different input signal. Optionally, multiple windows may be opened and instantiated for one particular input signal—providing the ability to modify most or all of a given input signal. Other variations and combinations of the teachings of the present invention are also comprehended. The embodiments of the present invention disclosed hereinafter are particularly useful for adding a tonal quality of warmth or depth, as perceived by an end-user, to a digital audio signal.

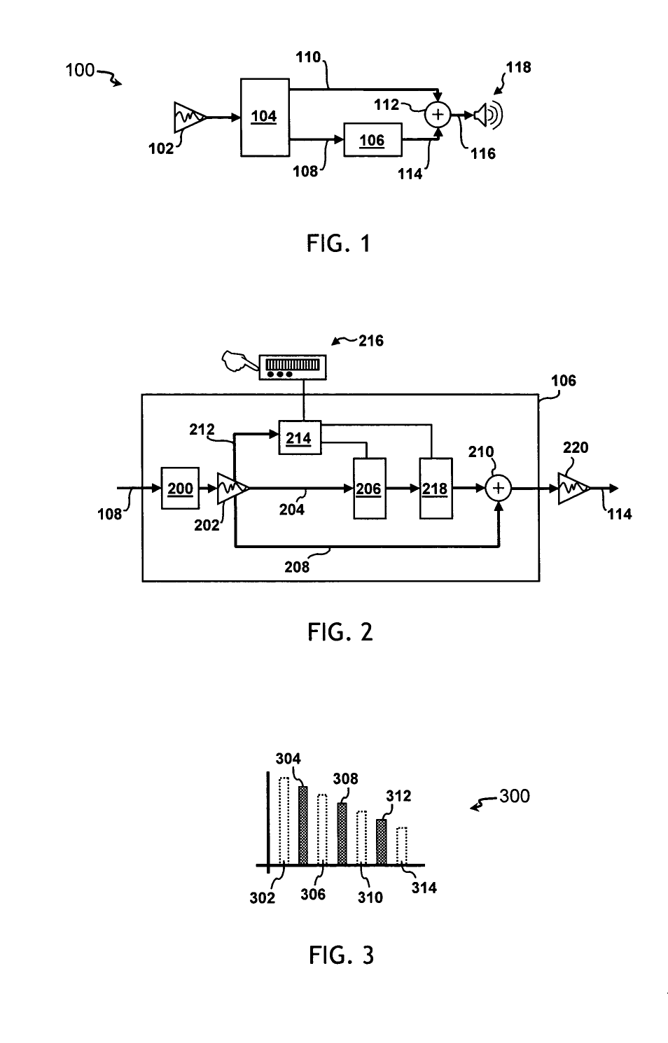

The present invention is disclosed in greater detail now with reference to FIG. 1. FIG. 1 depicts one embodiment of a signal processing system 100 according to the present invention. As depicted in FIG. 1, system 100 comprises an input signal source 102, a filtering function 104, and a processing function 106. Filtering function 104 conducts high pass, low pass, or a combination of high and low pass filtering on input signal 102. In system 100, the lower frequency ranges of signal 102 are passed 108 from function 104 to function 106. The higher frequency ranges of signal 102 are passed 110 from function 104 directly to a summing function 112. For purposes of explanation and illustration, system 100 thus separates signal 102 based on the presumption that the higher frequency ranges of signal 102 will not require processing according to the present invention. This presumption is based on the notion that in most commercial vocal and musical application, the higher frequency ranges typically will not require processing to reduce harshness—as such music would not be aesthetically pleasant to listen to. However, in applications where it is desirable to also process the higher frequency ranges of signal 102, function 104 may transfer 110 the higher frequency ranges of signal 102 to a second instance of function 106, or function 104 may be eliminated completely—sending the entire signal 102 directly to function 106.

Returning now to system 100 as depicted in FIG. 1, function 106 receives the lower frequency ranges of signal 102, and processes them as described hereinafter. Once function 106 completes processing in accordance with the present invention, it transfers 114 the newly modified low frequency portion of signal 102 to summing function 112. Summing function 112 combines the higher frequency portion with the modified lower frequency portion to form an output signal, and transfers the final output signal 116 to a desired output device 118.

In system 100, input signal 102 is presumed to be an already digitized sampling of an original analog signal. In alternative embodiments, however, signal 102 may be an original analog signal. In such a case, function 106 may comprise an analog-to-digital conversion function, as described hereinafter. Otherwise, in system 100, function 106 receives the lower frequency portion of the already digitized input signal 102.

Referring now to FIG. 2, processing function 106 is described in greater detail. As depicted in FIG. 2, function 106 comprises a signal acquisition function 200. In embodiments where transfer 108 presents an original analog signal 102, function 200 comprises an analog-to-digital (A/D) conversion function. In embodiments where transfer 108 presents an already digitized signal 102, then function 200 may comprise some signal preparation function (e.g., amplification or buffering), or may be omitted completely. The now-acquired input signal 202 is transferred from acquisition function 200. In embodiments where function 200 is omitted, signal 202 comprises unaltered signal 102 after transfer 108.

Input signal 202 is transferred 204 to a comparator function 206. Input signal 202 is also transferred 208 to summing function 210, and transferred 212 to user interface function 214. As described in greater detail hereinafter, user interface function 214 operates in communication and conjunction with user interface 216 to provide a user the ability to alter input signal 202 in accordance with the present invention. The user is given a modification “window” with which the user may selectively range through the frequency spectrum of input signal 202. The relative width of this band may be a fixed value (e.g., 35 Hz), or may be of a selectable width within a given range (e.g., 20 to 50 Hz). On a real-time basis, the instantaneous position (i.e., center) of an active window is identified as a fundamental frequency, and the fundamental frequency band is transferred from interface function 214 to comparator function 206. Comparator function 206 processes this information, analyzing the input signal at the current fundamental frequency band, and forwarding that portion of the is input signal to harmonics generation function 218.

As described in greater detail hereinafter, function 218 generates harmonics for the given portion of the input signal using a suitable algorithm, based on the selected fundamental frequency band and on a predetermined harmonics profile. In embodiments where a user is provided the ability to selectively alter the harmonics profile, the interface function 214 transfers a desired profile, as input by the user at interface 216, to harmonics function 218. Harmonics function 218 transfers the harmonics generated to summing function 210, where the harmonics are additively combined with input signal 202 at the selected fundamental frequency band to render a now-altered output signal 220. Signal 220 is then transferred 114 to summing function 112, in accordance with the description for FIG. 1 above.

Operationally, user interface 216 operates to receive and process signal modification inputs from a given user. User interface 216 may provide the user with auditory or visual representations of output signal 116 or, alternatively, may rely on auditory output from device 118 as the user's only feedback. Interface 216 provides the user with a modification window that the user may then adjust through a fixed range that corresponds to the frequency spectrum of input signal 202. As the user listens to and, in some embodiments, watches a visual representation of output signal 116, the user then begins to adjust the relative position of the modification window within the fixed range. The initial position of the modification window may be fixed within the spectrum, it may vary randomly, or it may initialize in the same relative position that it was last left. The relative position of the modification window, at any given instant, is translated into a fundamental frequency for use by function 106. Modification of signal 202 in accordance with the description relating to FIG. 2 is constant and real-time, so the output signal 116 experienced by the user, as modified by the selected harmonic profile at the instant fundamental frequency, provides the user with immediate perceptual response to adjustments in the position of the modification window. When the user finds a position of the modification window that provides a desirable aesthetic effect, the user may terminate the adjustment process.

As previously mentioned, user interface 216 presents a user with a modification window that may be implemented in a number of ways. Similarly, input received from a user via use of the modification window may be implemented in a number of ways. A number of integrated or separate software or hardware devices may be utilized or combined to provide the desired presentation and feedback mechanism for a given embodiment of the present invention. For example, in some embodiments, device 118 may be the only feedback mechanism provided to the user, requiring the user to listen to output signal 116 as he “tunes” the modification window of the present invention. In other embodiments, the user may be provided either a software or solid graphical feedback device, in combination with the audio feedback from device 118, to assist in determining a desirable position for the modification window. In some embodiments, a user's ability to adjust the relative position of the modification window within a signal spectrum may be implemented primarily with hardware—providing the user with a manual dial to turn. As the user turns the dial left or right, the relative position of the dial is translated to a corresponding fundamental frequency. Alternatively, the user's ability to adjust the modification window may be implemented primarily in software—providing a user the ability to adjust the relative position of the modification window either numerically or graphically. Furthermore, interface 216 and output device 118 may be separate or integrated devices, and may be separate from or integrated with a device housing system 100.

In certain embodiments, particularly those where most or all system functions are implemented in software, operation of system 100 may supplemented or enhanced with the introduction of storage or memory functions. Although memory functions are readily implemented in software, hardware-based recall mechanisms (e.g., a push-button dial preset) may also be provided. For a given input signal 102, a desired position for the signal modification window (e.g., a “lock” or a preset) may thus be stored mechanically, electro-mechanically or electronically, such that when a user wants to listen to the given input signal 102, he may immediately recall the desired modification setting. The user may, of course, be provided with the ability to access interface 216 and re-adjust the signal modification window starting from the recalled position. A user is thus provided with the capacity to customize and recall the aesthetic alteration performed for a given type of input signal (e.g., one window preset for jazz music, a second window preset for classical, etc.).

In other embodiments of the present invention, multiple instances of the modification window may be provided. Limited only by the practical storage and processing capabilities of the equipment within which system 100 is implemented, any desired number of modification windows may be presented to and adjusted by the user. Some or all of the relative positions of each such window may then be stored or locked in accordance with the teachings of the present invention. In certain embodiments of the present invention, multiple instances of the modification window are presented consecutively. A user is presented with a single modification window. Following the processes described above, the user adjusts the relative position of the modification window until finding a desired position for that window. The relative position of the window may then be stored or locked, or the user may simply leave that window in its desired position. The user is then prompted, via an electronic, electro-mechanical or mechanical device, with the presentation of the next sequential modification window, and the process repeats a desired number of times.

In other embodiments, the user is presented with a desired number of modification windows concurrently. Some or all of the windows may start in a single default position within the frequency spectrum of input signal 202. Alternatively, some or all of the windows may start in positions within the frequency spectrum varied according to a predetermined distribution scheme (e.g., at preset positions, at random positions, etc.). The user may be required to begin adjustment with one particular window, or may be provided with a choice of which window to start with. The user may be provided with individual adjustment control for each window or, alternatively, may be provided with a single adjustment control adapted to cycle through each of the modification windows presented.

In the embodiment depicted in FIG. 2, harmonics function 218 operates on a predetermined harmonics profile to generate a desired number of signal harmonics having desired characteristics. System 100 utilizes any suitable algorithm that produces the desired signal harmonics according the harmonics profile. This profile is now described in greater detail with reference to FIG. 3. FIG. 3 depicts a harmonics profile 300, comprising first through seventh order harmonics 302 through 314, respectively. In this embodiment of the present invention, the relative weighting of each harmonic decreases as the order increases, resulting in a negative slope for profile 300. The relative weight, and the amount by which the weighting decreases, may be varied uniformly across all orders, or may be varied from order to order. For example, the weight of order 312 may be equal to 50% of the weight of order 308, which itself is equal to 66% of the weight of order 304, which is itself equal to 75% of the amplitude of signal 202. This would result in a uniform ¾, ½ and ¼ harmonics profile for the second, fourth and sixth harmonics, respectively. In alternative embodiments, the variances may be selected to be any other uniform or non-uniform desired values. For example, the weight of order 312 may be equal to 72% of the weight of order 308, which itself is equal to 57% of the weight of order 304. Again, the weightings of each order may be varied widely, required only to decrease in value as the order number increases.

Profile 300 activates only the even-order second, fourth and sixth harmonics 304, 308 and 312, respectively. Odd order harmonics 302, 306, 310 and 314 are not processed by harmonics function 218. Further even order harmonics (e.g., eighth, tenth, etc.) may be included as desired, although the recognizable effect realized from their inclusion may be limited.

Profile 300 contrasts with conventional schemes, many of which rely on an increasing slope and incorporate both odd and even order harmonics. The present invention recognizes that for a number of end-users, the addition of odd order harmonics to an audio signal adds a degree of aesthetic harshness. Thus, odd order harmonics are omitted from profile 300. In further contrast is the negative slope of profile 300. In many cases, conventional schemes employ a positive slope, increasing the relative weight of higher order harmonics. The present invention recognizes that for a number of end-users, the addition of even order harmonics in a decreasing slope arrangement provides an enhanced perception of warmth in the audible signal.

Alternative embodiments of the present invention allow the user to selectively modify some or all characteristics of profile 300. Such modifications may be made via mechanical, electro-mechanical, or electronic devices as disclosed herein. An end-user may be provided the ability to select which of orders 304, 308 or 312 to include in the profile. As user may further be provided the ability to include higher order even harmonics (e.g., eighth, tenth, etc.). A user may be provided the ability to include, if desired, odd order harmonics. A user may be provided the ability to selectively adjust the relative weightings of each order, by fixed or adjustable amounts. In one embodiment of the present invention, for example, a user may, via a software interface, adjust profile 300 to include only harmonics 304, 306 and 308. The user may further select a relative weight for order 308 equal to 80% of order 306. The user may select a relative weight for order 306 equal to 50% of order 304. Finally, the user may set a relative weight value for order 304 that provides a desirable aesthetic effect. These and other variations are comprehended by the present invention.

In all embodiments of the present invention, each functional instance or operational device may be implemented in a number of ways, depending upon a variety of factors (e.g., the type of equipment within which the system will be implemented, the technical sophistication of the end-user, etc.). Any number of mechanical, electro-mechanical or electronic devices or contrivances may be used, individually or in combination, to provide a necessary or desired functionality or feature. For example, output device 118 may comprise a stand-alone stereo speaker or a speaker integrated within a laptop computer. Functional instances 200, 206, 210, 214 and 218 may be implemented individually (e.g., within individual semiconductor devices), or partially or completely combined within a single device (e.g., functional operations programmed into a processor). User input mechanisms may comprise solid-state, “vintage” components (e.g., manual tuners or toggle switches) or automated electronic mechanisms (e.g., software prompts running on a computer). Similarly, user feedback mechanisms may comprise solid-state, “vintage” components (e.g., a mechanical dial) or electronic assemblies (e.g., a liquid crystal display). Other variations, and a wide variety of partial and complete combinations of the above, are possible and fully comprehended hereby.

The embodiments and examples set forth herein are presented to best explain the present invention and its practical application and to thereby enable those skilled in the art to make and utilize the invention. However, those skilled in the art will recognize that the foregoing description and examples have been presented for the purpose of illustration and example only. The description as set forth is not intended to be exhaustive or to limit the invention to the precise form disclosed. Many modifications and variations are possible in light of the above teaching without departing from the spirit and scope of the following claims.

1. A method of processing a digital audio signal, comprising the steps of:
providing a digital audio signal having a defined frequency spectrum;
providing and operating a user interface to select a fundamental frequency from the frequency spectrum;
providing a harmonics generation function to generate a number of signal harmonics based on the fundamental frequency; and
adding the signal harmonics to the digital audio signal at the fundamental frequency.

2. The method of claim 1, wherein the step of providing a digital audio signal further comprises the steps of:
providing an analog audio signal;
providing an analog to digital conversion function; and
converting the analog audio signal into the digital audio signal using the analog to digital conversion function.

3. The method of claim 1, wherein the step of providing and operating a user interface further comprises providing a user input mechanism and a user feedback mechanism.

4. The method of claim 3, wherein the step of providing and operating a user interface further comprises providing an auditory user feedback mechanism.

5. The method of claim 3, wherein the step of providing and operating a user interface further comprises providing a visual user feedback mechanism.

6. The method of claim 3, wherein the step of providing and operating a user interface further comprises providing both visual and auditory user feedback mechanisms.

7. The method of claim 3, wherein the step of providing and operating a user interface further comprises providing a mechanical user input mechanism.

8. The method of claim 3, wherein the step of providing and operating a user interface further comprises providing an electro-mechanical user input mechanism.

9. The method of claim 3, wherein the step of providing and operating a user interface further comprises providing an electronic user input mechanism.

10. The method of claim 3, wherein the step of providing and operating a user interface further comprises providing a signal modification window.

11. The method of claim 10, wherein the step of providing and operating a user interface further comprises providing a user the ability, via the user input mechanism, to move the signal modification window through the frequency spectrum to a desired fundamental frequency position.

12. The method of claim 11, further comprising the step of providing a memory function.

13. The method of claim 12, further comprising the step of storing, within the memory 2 function, information on the modification window's relative position.

14. The method of claim 13, further comprising the step of storing, within the memory function, information correlating the information on the modification window's relative position to a particular type of digital audio signal.

15. The method of claim 12, wherein the step of providing and operating a user interface further comprises providing a plurality of signal modification windows, and wherein information on each modification window's relative position is stored within the memory function.

16. The method of claim 1, wherein the step of providing a harmonics generation function further comprises providing a desired harmonics profile.

17. The method of claim 16, wherein the step of providing a harmonics generation function further comprises providing an algorithm that generates signal harmonics, according to the desired harmonics profile, of the digital audio signal at the fundamental frequency.

18. The method of claim 16, wherein the step of providing a harmonics generation function further comprises providing a desired harmonics profile, wherein the harmonics profile comprises harmonics that decrease in relative weight as relative order increases.

19. The method of claim 18, wherein the step of providing a desired harmonics profile further comprises providing only even order harmonics.

20. The method of claim 19, wherein the wherein the harmonics profile comprises only second, fourth and sixth harmonics.

21. The method of claim 18, wherein the step of providing a desired harmonics profile further comprises step of providing a user, via the user interface, the ability to selectively alter which harmonics are included in the harmonics profile.

22. The method of claim 18, wherein the step of providing a desired harmonics profile further comprises step of providing a user, via the user interface, the ability to selectively alter the relative weight of each harmonic included in the harmonics profile.

23. A device for processing digital signals comprising:
a signal acquisition function adapted to output a digital input signal;
a user interface function, communicatively coupled to a user interface, adapted to receive the digital input digital audio signal and to provide a user-selected fundamental frequency;
a comparator function, adapted to receive the digital input digital audio signal and the user-selected fundamental frequency, and to output a portion of the digital input signal at the user-selected fundamental frequency;
a harmonics generation function, adapted to receive from the comparator function the portion of the digital input signal at the user-selected fundamental frequency, and to generate a number of signal harmonics for the portion of the digital input signal at the user-selected fundamental frequency based on a defined harmonics profile; and
a summing function, adapted to receive the signal harmonics from the harmonics generation function and to add the signal harmonics to the digital input signal at the user-selected fundamental frequency.

24. The device of claim 23, wherein each of the functions is implemented in a separate device.

25. The device of claim 23, wherein two or more of the functions are integrated within a single device.

26. The device of claim 23, wherein the signal acquisition function comprises an analog to digital conversion function.

27. The device of claim 23, wherein the user interface function and the user interface are cooperatively adapted to provide a signal modification window, by which an end-user selects a fundamental frequency.

28. The device of claim 27, wherein the user interface comprises a user input mechanism and a user feedback mechanism.

29. The device of claim 28, wherein the user feedback mechanism comprises an auditory user feedback mechanism.

30. The device of claim 28, wherein the user feedback mechanism comprises a visual user feedback mechanism.

31. The device of claim 28, wherein the user feedback mechanism comprises both visual and auditory user feedback mechanisms.

32. The device of claim 28, wherein the user interface further comprises a mechanical user input mechanism.

33. The device of claim 28, wherein the user interface further comprises an electro-mechanical user input mechanism.

34. The device of claim 28, wherein the user interface further comprises an electronic user input mechanism.

35. The device of claim 23, wherein the user interface and harmonics generation functions are further adapted to generate and process, respectively, a user-adapted harmonics profile.

36. A system for providing user-modified processing of a digital audio signal, the system comprising:
a digital input audio signal having a defined signal spectrum;
a harmonics profile, adapted to specify generation of a second harmonic of weight equal to 75% of the digital input audio signal, a fourth harmonic of weight equal to 50% of the digital input audio signal, and a sixth harmonic of weight equal to 25% of the digital input audio signal;
a harmonics generation function, adapted to generate the harmonics specified in the harmonics profile from the digital input audio signal at a user-selected fundamental frequency;
a summing function, adapted to add the harmonics generated by the harmonics generation function to the digital input audio signal at the user-selected fundamental frequency to generate a modified output audio signal;
a user feedback mechanism adapted to communicate the modified output audio signal to a user; and
a user interface, adapted to provide the user the ability to move the user-selected fundamental frequency throughout the signal spectrum of the digital input audio signal.
